(19) United States
(12) Patent Application Publication
(10) Pub. No.: US 2025/0267858 A1
(43) Pub. Date: Aug. 21, 2025

(54) SEMICONDUCTOR DEVICE AND MANUFACTURING METHOD OF THE SAME

(71) Applicant: Kioxia Corporation, Tokyo (JP)

(72) Inventor: Shoji AOTA, Yokkaichi Mie (JP)

(21) Appl. No.: 19/054,480

(22) Filed: Feb. 14, 2025

(30) Foreign Application Priority Data
Feb. 16, 2024 (JP) 2024-022064

(51) Int. Cl. H10B 20/25; H10D 62/834; H10D 64/66; H10D 64/68

(52) U.S. Cl. CPC H10B 20/25; H10D 62/834; H10D 64/666; H10D 64/667; H10D 64/691

(57) ABSTRACT

A semiconductor device includes a semiconductor substrate including an active region and an isolation region that is electrically isolated from the active region, a fuse disposed on the isolation region and including a polysilicon layer including an impurity, and first and second electrode layers that are electrically connected to the polysilicon layer, and a transistor disposed on the active region and including a metal gate having a stack structure of electrode layers.

### CROSS-REFERENCE TO RELATED APPLICATIONS

This application is based upon and claims the benefit of priority from Japanese Patent Application No. 2024-022064, filed Feb. 16, 2024, the entire contents of which are incorporated herein by reference.

### FIELD

Embodiments described herein relate generally to a semiconductor device and a manufacturing method of the same.

### BACKGROUND

An electrically programmable fuse (e-Fuse) has a fuse region that can be electrically broken by a write operation or a programming operation, and can reduce an occupancy area on a chip. Therefore, it is used in a central processing unit (CPU), various kinds of memory devices, and large scale integration such as application specific integrated circuits (ASIC).

### BRIEF DESCRIPTION OF THE DRAWINGS

FIG. 1A is a plan view of a fuse of a semiconductor device according to an embodiment.

FIG. 1B is a sectional view along I-I line in FIG. 1A.

FIG. 2A is a plan view for illustrating a first manufacturing method of the fuse of the semiconductor device.

FIG. 2B is a sectional view along II-II line in FIG. 2A.

FIG. 3A is a plan view for illustrating the first manufacturing method of the fuse of the semiconductor device.

FIG. 3B is a sectional view along III-III line in FIG. 3A.

FIG. 4A is a plan view for illustrating the first manufacturing method of the fuse of the semiconductor device.

FIG. 4B is a sectional view along IV-IV line in FIG. 4A.

FIG. 5A is a plan view of the first manufacturing method of the fuse of the semiconductor device according to the embodiment.

FIG. 5B is a sectional view along a V-V line in FIG. 5A.

FIG. 6A is a plan view for illustrating the first manufacturing method of the fuse of the semiconductor device.

FIG. 6B is a sectional view along VI-VI line in FIG. 6A.

FIG. 7A is a plan view for illustrating the first manufacturing method of the fuse of the semiconductor device.

FIG. 7B is a sectional view along VII-VII line in FIG. 7A.

FIG. 8A is a plan view for illustrating the first manufacturing method of the fuse of the semiconductor device.

FIG. 8B is a sectional view along VIII-VIII line in FIG. 8A.

FIG. 9A is a plan view for illustrating the first manufacturing method of the fuse of the semiconductor device.

FIG. 9B is a sectional view along IX-IX line in FIG. 9A.

FIG. 10A is a plan view for illustrating the first manufacturing method of the fuse of the semiconductor device.

FIG. 10B is a sectional view along X-X line in FIG. 10A.

FIG. 11A is a plan view for illustrating a second manufacturing method of the fuse of the semiconductor device.

FIG. 11B is a sectional view along XI-XI line in FIG. 11A.

FIG. 12A is a plan view for illustrating the second manufacturing method of the fuse of the semiconductor device.

FIG. 12B is a sectional view along XII-XII line in FIG. 12A.

FIG. 13A is a plan view for illustrating the second manufacturing method of the fuse of the semiconductor device.

FIG. 13B is a sectional view along XIII-XIII line in FIG. 13A.

FIG. 14A illustrates a pattern disposition example 1 of a contact and a polysilicon layer.

FIG. 14B illustrates a pattern disposition example 2 of the contact and the polysilicon layer.

FIG. 14C illustrates a pattern disposition example 3 of the contact and the polysilicon layer.

FIG. 14D illustrates a pattern disposition example 4 of the contact and the polysilicon layer.

FIG. 14E illustrates a pattern disposition example 5 of the contact and the polysilicon layer.

FIG. 15A is a sectional view of a fuse of a semiconductor device according to a modification 1.

FIG. 15B is a sectional view of a fuse of a semiconductor device according to a modification 2.

FIG. 15C is a sectional view of a fuse of a semiconductor device according to a modification 3.

FIG. 15D is a sectional view of a fuse of a semiconductor device according to a modification 4.

FIG. 16A is a plan view of a fuse of a semiconductor device according to a modification 5.

FIG. 16B is a sectional view along XVI-XVI line in FIG. 16A.

FIG. 17A is a plan view of an NMOS transistor in a semiconductor device according to an embodiment.

FIG. 17B is a sectional view along XVII-XVII line in FIG. 17A.

FIG. 18A is a plan view of a PMOS transistor in a semiconductor device according to an embodiment.

FIG. 18B is a sectional view along XVIII-XVIII line in FIG. 18A.

### DETAILED DESCRIPTION

When replacement metal gate (RMG) technology is applied, since polysilicon serving both as a polysilicon gate electrode and a fuse is replaced with a metal gate material, the polysilicon cannot be used as a fuse.

Embodiments of this disclosure provide a highly reliable semiconductor device in which polysilicon is applicable to a fuse and a manufacturing method of the same.

In general, according to one embodiment, a semiconductor device comprises: a semiconductor substrate including an active region and an isolation region that is electrically isolated from the active region; a fuse disposed on the isolation region and including: a polysilicon layer including an impurity, and first and second electrode layers that are electrically connected to the polysilicon layer; and a transistor disposed on the active region and including a metal gate having a stack structure of electrode layers.

Hereinafter, embodiments will be described with reference to the drawings. Note that, in the following description, same or similar members or the like are denoted by same signs, and the description is appropriately omitted for members described once. In the following description, the direction perpendicular to a semiconductor substrate on XY plane is defined as Z direction, the direction which is orthogonal to Z direction and in which a polysilicon layer to be a fuse stretches is defined as X direction, and the direction perpendicular to Z and X directions is defined as Y direction.

### (Configuration of Semiconductor Device)

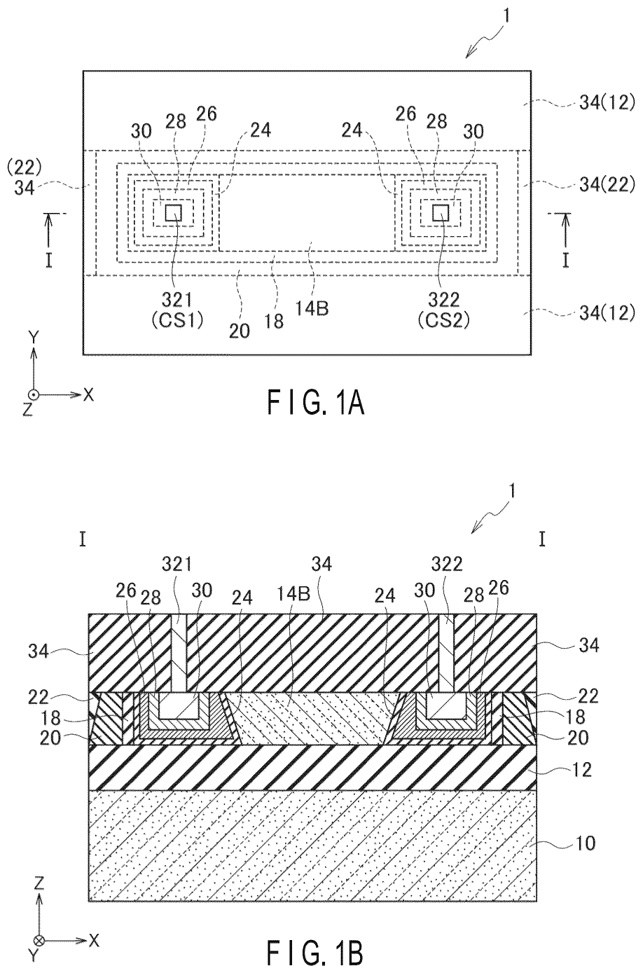

FIG. 1A is a plan view of a fuse 1 of a semiconductor device according to an embodiment. FIG. 1B is a sectional view along I-I line in FIG. 1A.

The semiconductor device according to the present embodiment includes the fuse 1 and a transistor provided on a semiconductor substrate 10. The semiconductor device realizes a polysilicon fuse (poly fuse) structure by complementary metal oxide semiconductor (CMOS) device technology for which HKMG technology by a high-k dielectric (HK: High-k)/metal gate (MG) and RMG technology are combined.

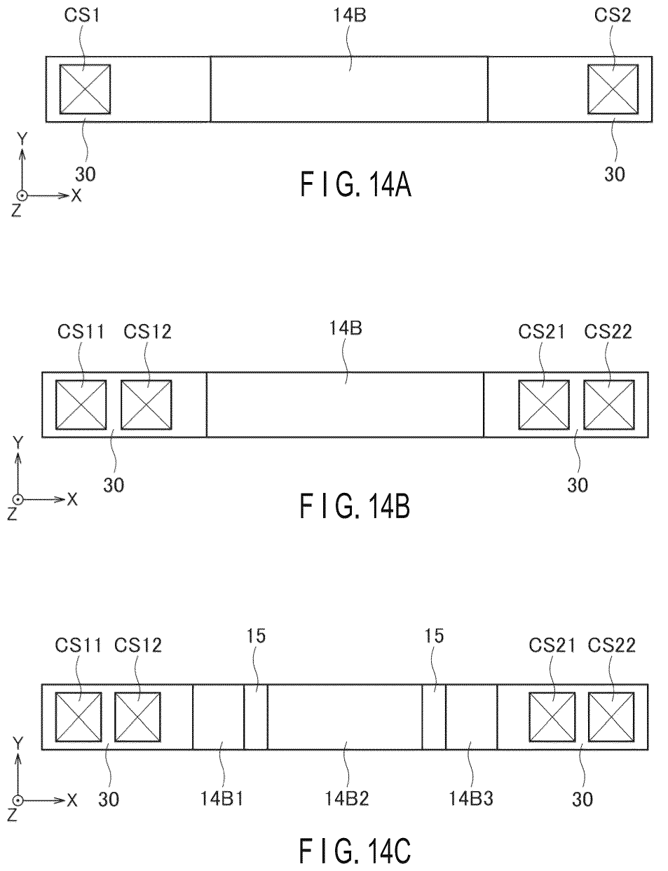

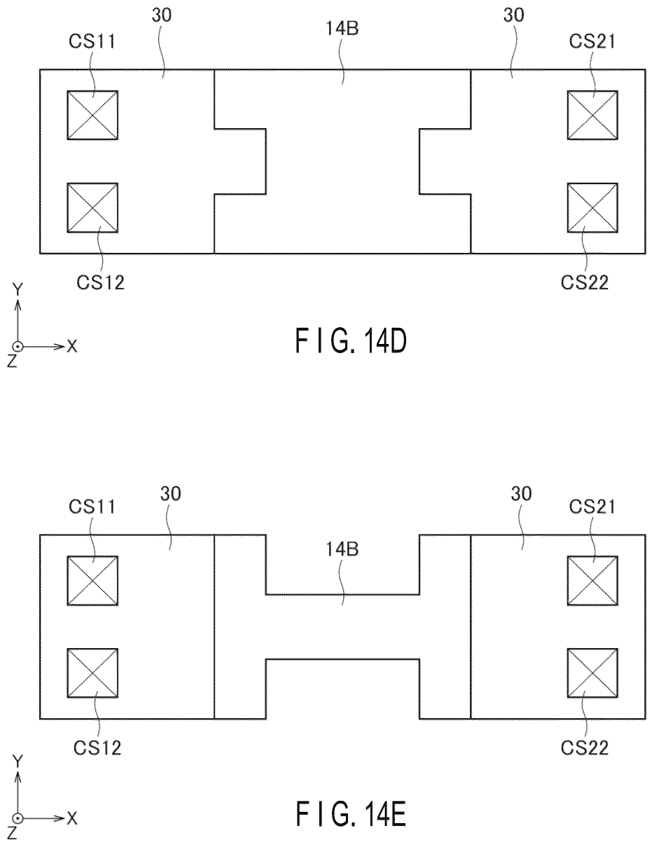

As illustrated in FIG. 1A and FIG. 1B, the fuse 1 includes an isolation region 12 provided on the semiconductor substrate 10 such as a semiconductor wafer, a polysilicon layer 14B which is provided on the isolation region 12 and for which a dummy polysilicon layer 14 is doped with an impurity, and electrode layers (26, 28, and 30) which are provided on the isolation region 12, replace the dummy polysilicon layer 14, and electrically connected with the polysilicon layer 14B. In addition, a first electrode 321 and a second electrode 322 electrically connected with the electrode layers (26, 28, and 30) are provided. The first electrode 321 and the second electrode 322 configure electrode terminals of the fuse 1. The first electrode 321 is connected to the metal electrode layer 30 via a contact CS1. The second electrode 322 is connected to the metal electrode layer 30 via a contact CS2. Note that a plurality of pattern disposition examples of the contact and the polysilicon layer will be described later in the description of FIG. 14A to FIG. 14E. The electrode layers (26, 28, and 30) are provided on both ends of the polysilicon layer 14B that stretches in X direction on the isolation region 12. The isolation region 12 is an insulating layer called shallow trench isolation (STI).

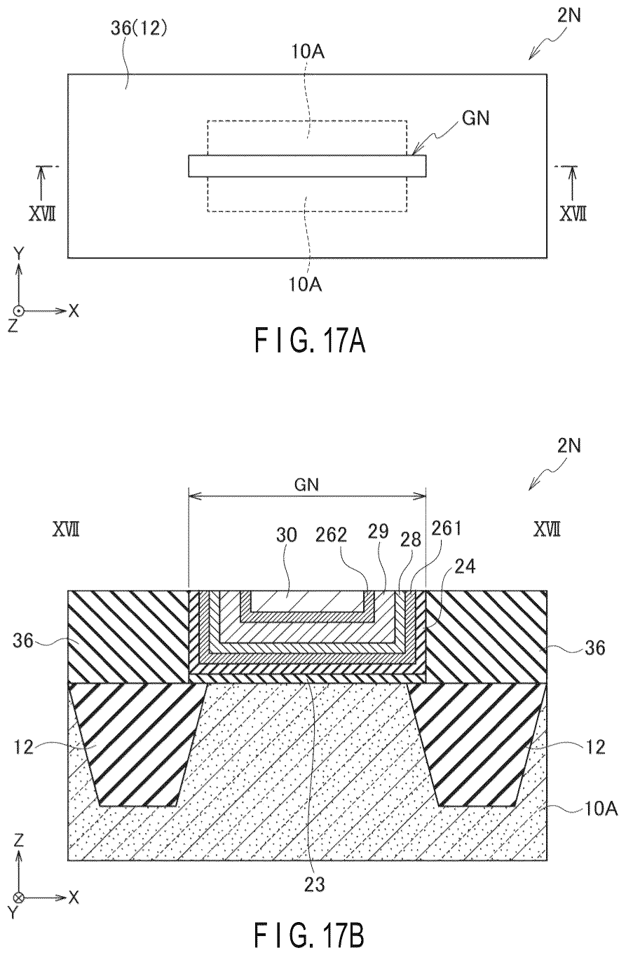

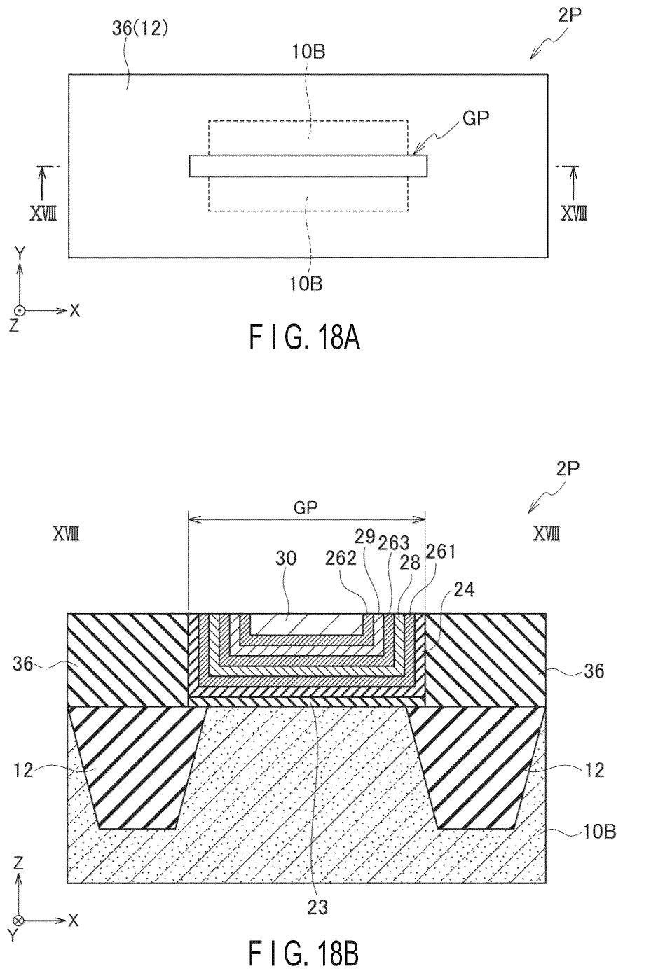

The transistor includes a metal gate which is provided on an active region electrically isolated by the isolation region 12 and includes a stack structure of the electrode layers (26, 28, and 30). The transistor will be described later in the description of FIG. 17A, FIG. 17B, FIG. 18A, and FIG. 18B.

As illustrated in FIG. 1A and FIG. 1B, the fuse 1 includes a stack structure of a high-k dielectric layer 24, a metal-containing layer 26 provided on the high-k dielectric layer 24, a work function metal (WF) layer 28 provided on the metal-containing layer 26, and the metal electrode layer 30 provided on the work function metal layer 28. Though illustration is omitted in FIG. 1A and FIG. 1B, an oxide film (IL: Inter Layer; SiO2) is provided between the high-k dielectric layer 24 and the isolation region 12.

For the high-k dielectric layer 24, a dielectric constant k is 10 or larger for example, and hafnium oxide (HfO2), hafnium silicate (HfSiO), tantalum oxide (Ta2O5), strontium titanate (SrTiO3), or zirconium oxide (ZrO2) or the like is applicable.

For the metal-containing layer 26, titanium nitride (TiN), tantalum nitride (TaN), tantalum (Ta), or tungsten (W) or the like is applicable. For example, with TiN, an interface with the polysilicon layer 14B is silicided by TiN. Therefore, a connection part of the polysilicon layer 14B and the electrode layers (26, 28, and 30) is made low in resistance. In any case of TaN, Ta, or W, since the interface with the polysilicon layer 14B is silicided by silicide of TaN, Ta, or W, the connection part is made low in resistance.

In the HKMG technology, the thin work function metal layer 28 is inserted between the high-k dielectric layer 24 and the metal electrode layer 30. A threshold voltage can be adjusted by changing a thickness of the work function metal layer 28. The work function metal layer 28 may contain a metal such as aluminum (Al) or lanthanum (La).

As the metal electrode layer 30, for example, W or Al or the like is applicable.

The fuse 1 is electrically programmable by breaking the polysilicon layer 14B by a voltage applied between the first electrode 321 and the second electrode 322.

In the fuse 1, by ion-implanting boron (B) for example as an impurity into the dummy polysilicon layer 14, a B-doped polysilicon layer 14B can be selectively left at an arbitrary part even after an RMG process, to be utilized as a polysilicon fuse. A heat treatment process may be added after a Bion implantation process.

In the fuse 1, the polysilicon layer 14B can be left at any part just by adding an impurity ion implantation process even in the RMG process which does not leave the dummy polysilicon layer 14, and the polysilicon fuse can be realized. A bonding surface of the polysilicon layer 14B and the electrode layers (26, 28, and 30) can be controlled to be in any shape by adjusting an implantation impurity profile of the polysilicon layer 14B.

In the fuse 1, there is no need to dispose a material having different resistivity in a material of a fuse formation layer. Therefore, the need for a layout of narrowing a line width and concentrating electric power on a breaking part to break the fuse is eliminated, and an occupancy area of the fuse can be reduced.

In the fuse 1, since the polysilicon layer is applicable to the fuse, designing can be performed by a layout method finer than a metal fuse using a metal wiring layer, and a fuse area can be reduced. In the metal fuse using the metal wiring layer, there is a reliability defect that a broken part is bonded again due to an electromigration (EM) or stress migration (SM) phenomenon in a long term and fuse information lacks. In the fuse 1, since the polysilicon layer is applicable to the fuse, a broken part is not bonded again due to the EM or SM phenomenon, and a fuse structure having higher reliability in information holding than the metal fuse can be realized.

In the fuse 1, by selectively implanting the impurity (B) into the dummy polysilicon layer 14 replaced in the RMG process, an etching rate of the polysilicon is lowered, and the polysilicon layer 14B that functions as the fuse even after the RMG process can be left. Therefore, the fuse structure of the polysilicon can be easily realized even in an RMG process applied device.

In the fuse 1, a shape of the connection part with the electrode layers (26, 28, and 30) can be controlled to be any shape by controlling a profile of impurity implantation of the polysilicon layer 14B to be left as the fuse, and it is possible to adjust a contact area of the polysilicon layer 14B and the electrode layers (26, 28, and 30) and reduce contact resistance.

For example, while W wiring is generally used for lower layer wiring in a memory device, W has a fusing point as high as 3407° C. and is unsuitable for the metal fuse structure. In this case, the fuse is formed by Cu (fusing point 1084.5° C.) or Al (fusing point 660° C.) wiring or the like of upper layer wiring, however, since a design rule of the upper layer wiring is relatively large, a fuse layout area increases. In the fuse 1, by the polysilicon (fusing point 1410° C.), the occupancy area of the fuse is reduced and the highly reliable fuse structure can be realized.

When the direction in which the polysilicon layer 14B stretches is X direction and the direction perpendicular to the semiconductor substrate 10 is Z direction, in a sectional structure along XZ plane of the polysilicon layer 14B, a first bonding surface between the polysilicon layer 14B and the electrode layers (26, 28, and 30) connected to the first electrode 321 and a second bonding surface between the polysilicon layer 14B and the electrode layers (26, 28, and 30) connected to the second electrode 322 can be formed to have various arbitrary shapes.

As illustrated in FIG. 1B, the fuse 1 has an inversely tapered shape in Z direction in the sectional structure along XZ plane of the polysilicon layer 14B. Since this bonding part shape can widen an area as compared to a case of perpendicularly forming the bonding surface, the contact resistance of the bonding surface can be reduced.

### (Impurity Ion Implantation)

By implanting the impurity (B) into the dummy polysilicon layer 14, the etching rate can be controlled so as not to remove the boron-doped polysilicon layer 14B even in the RMG process. A timing of impurity ion implantation into the dummy polysilicon layer 14 may be in an arbitrary process before peeling the dummy polysilicon layer 14 by the RMG process. As to be described later in a semiconductor device manufacturing method, it can be realized either before or after processing the fuse structure.

In addition, a shape of an end part of the polysilicon layer 14B when etching the dummy polysilicon layer 14 can be controlled by controlling the impurity profile of the polysilicon layer 14B to be the fuse. As the shape of the end part of the polysilicon layer 14B, the impurity profile of the polysilicon layer 14B can be controlled so as to be an inversely tapered, tapered, parallelogram, barrel or hand drum shape, for example. In the ion implantation, oblique ion implantation may be executed, or the ion implantation may be executed in multiple stages in order to adjust the shape. A dose amount and acceleration energy at the time of the ion implantation may be changed. Further, a heat treatment process may be appropriately added.

A value of etch selectivity is about 15 when a value of boron impurity concentration is 1×10²⁰ cm−3, and a value of etch selectivity is about 100 or larger when the value of the boron impurity concentration is 1×10²¹ cm−3. Even when the value of the boron impurity concentration is 1×10¹⁹ cm−3, allowable etch selectivity is obtained. Thus, the value of the boron impurity concentration is preferably at least about 1×10¹⁹ cm−3 or larger.

By forming a bonding area of the polysilicon layer 14B and the electrode layers (26, 28, and 30) to be large, a part where the fuse is to be broken is moved to the inside of the polysilicon layer 14B of higher resistance compared to the electrode layers (26, 28, and 30), and a breaking region can be limited. In addition, by increasing the bonding area of the polysilicon layer 14B and the electrode layers (26, 28, and 30), an area of a contact CS of the first electrode 321 and the second electrode 322, and the metal electrode layer 30 can be formed to be small.

(Semiconductor Device Manufacturing Method according to Embodiment)

In a semiconductor device manufacturing method according to an embodiment, the electrically programmable fuse 1 is formed on the isolation region 12 of the semiconductor substrate 10, and the transistor is formed on the active region of the semiconductor substrate 10.

For the fuse 1, the dummy polysilicon layer 14 is formed on the isolation region 12, the polysilicon layer 14B for which the dummy polysilicon layer 14 is doped with the impurity is formed, the dummy polysilicon layer 14 is removed by etching to leave the polysilicon layer 14B on the isolation region 12, and the electrode layers (26, 28, and 30) electrically connected to the polysilicon layer 14B are formed instead of the dummy polysilicon layer 14.

For the transistor, the dummy polysilicon layer is formed above the active region, then the dummy polysilicon layer is removed by etching, and a metal gate is formed instead of the dummy polysilicon layer.
First Manufacturing Method

In a first manufacturing method of the fuse 1 of the semiconductor device, the isolation region 12 is formed on the semiconductor substrate 10, a non-doped dummy polysilicon layer 14 is formed on the isolation region 12, the polysilicon layer 14B for which the dummy polysilicon layer 14 is doped with the impurity is formed by lithography and ion implantation technology, an insulating layer 18 is formed on an entire surface, then the dummy polysilicon layer 14 is processed to expose a surface of the isolation region 12, an interlayer insulating film 22 is formed on the entire surface, flattening is performed by flattening treatment, a surface of the polysilicon layer 14B is exposed, the polysilicon layer 14B is left and the dummy polysilicon layer 14 is removed to expose the surface of the isolation region 12 by etching, the electrode layers (26, 28, and 30) are formed on the entire surface, the surfaces of the electrode layers (26, 28, and 30) and the polysilicon layer 14B are exposed flatly by the flattening treatment, an interlayer insulating film 34 is formed on the entire surface, and the first electrode 321 and the second electrode 322 are formed for the electrode layer 30 by patterning.

In the first manufacturing method of the fuse 1, in processes, the impurity is ion-implanted into the dummy polysilicon layer 14 before processing the dummy polysilicon layer 14. Therefore, dimensional controllability in processes is relatively low and manufacture is easy.

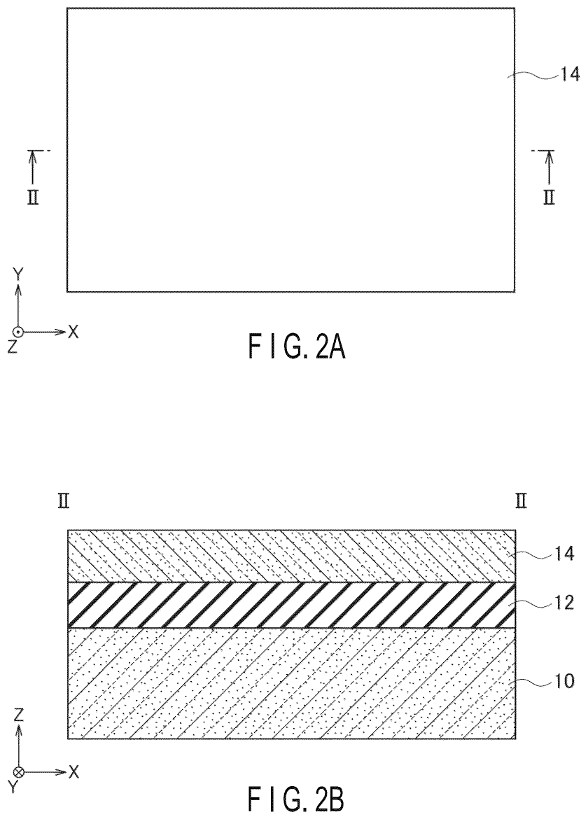

(A) FIG. 2A is a plan view for illustrating the first manufacturing method, and FIG. 2B is a sectional view along II-II line in FIG. 2A. First, as illustrated in FIG. 2A and FIG. 2B, the dummy polysilicon layer 14 is formed on the semiconductor substrate 10. The dummy polysilicon layer 14 is formed on the isolation region 12 formed on the semiconductor substrate 10. The dummy polysilicon layer 14 becomes the polysilicon layer 14B for the fuse after doping, but is called a dummy polysilicon layer since the electrode part is replaced with a metal electrode by the RMG process.

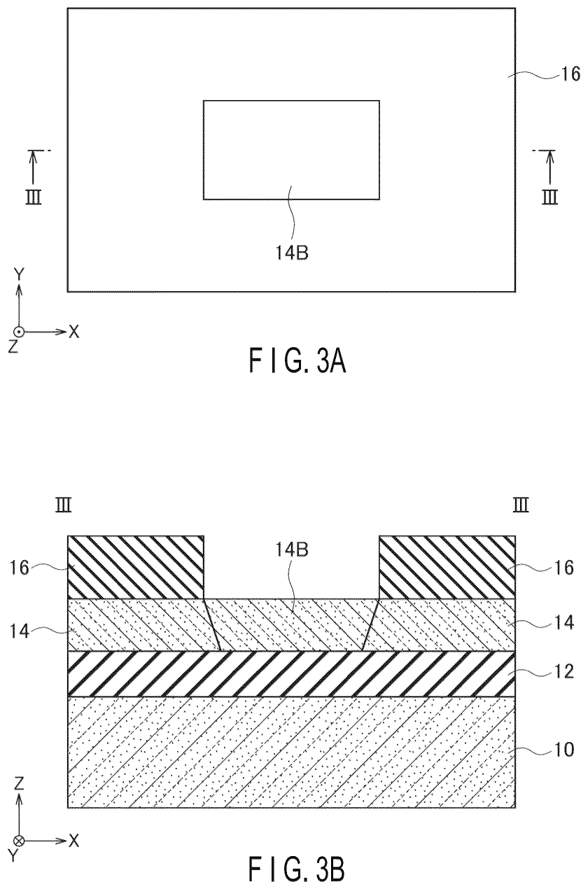

(B) FIG. 3A is a plan view for illustrating the first manufacturing method and FIG. 3B is a sectional view along III-III line in FIG. 3A. Next, as illustrated in FIG. 3A and FIG. 3B, after applying a resist layer 16 on the dummy polysilicon layer 14, window opening for the dummy polysilicon layer 14 is executed by a lithography process, and ion implantation of impurity ions is performed. Here, as the impurity, boron (B) can be used for example. An ion implantation depth and an impurity concentration distribution of boron for the dummy polysilicon layer 14 can be controlled by the acceleration energy and the dose amount. In addition, an annealing treatment process may be executed after the ion implantation of boron. The ion implantation of boron may be executed in multiple stages. Further, oblique ion implantation technology may be used together. Here, the polysilicon layer 14B in which boron is ion-implanted is a region to be the polysilicon fuse.

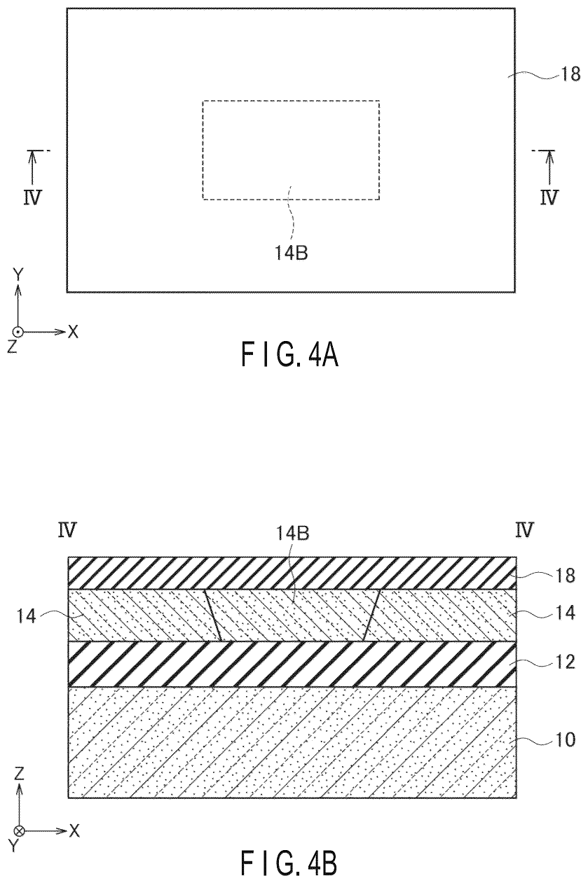

(C) FIG. 4A is a plan view for illustrating the first manufacturing method and FIG. 4B is a sectional view along IV-IV line in FIG. 4A. Next, as illustrated in FIG. 4A and FIG. 4B, after peeling the resist layer 16, the insulating layer (Cap film) 18 is formed on the polysilicon layer 14B and the dummy polysilicon layer 14. Here, as the insulating layer 18, a silicon nitride film (SiN) can be used for example. The insulating layer 18 can be used as a hard mask.

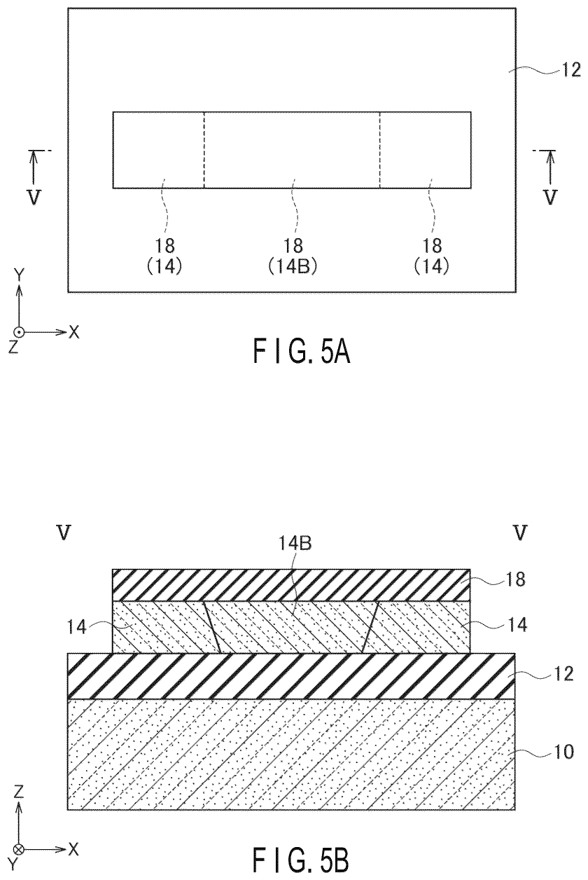

(D) FIG. 5A is a plan view for illustrating the first manufacturing method and FIG. 5B is a sectional view along V-V line in FIG. 5A. Next, as illustrated in FIG. 5A and FIG. 5B, with the insulating layer 18 as the hard mask, the dummy polysilicon layer 14 is removed by etching technology such as reactive ion etching (RIE), and the surface of the isolation region 12 is exposed. As a result, the processed dummy polysilicon layer 14 and polysilicon layer 14B are formed on the isolation region 12.

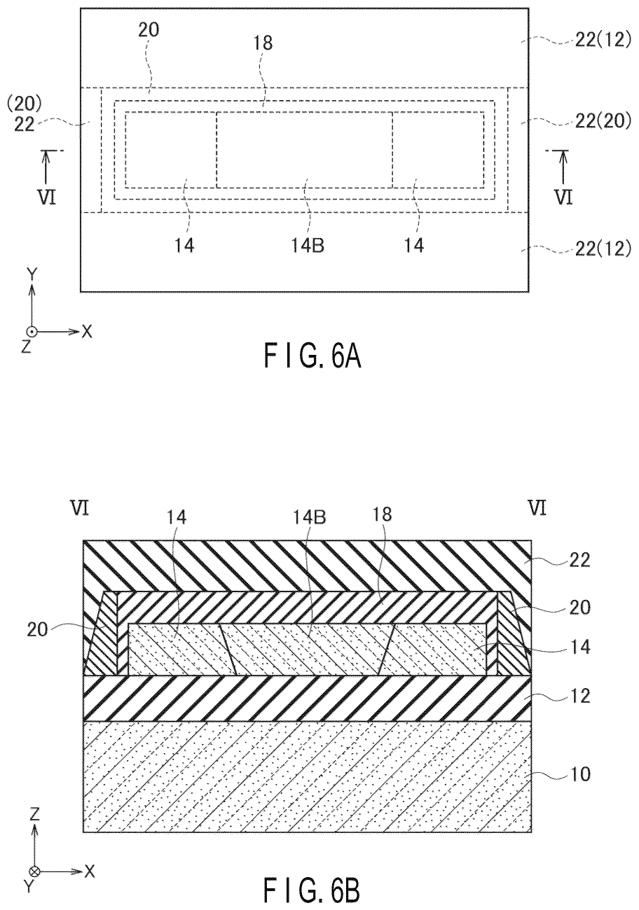

(E) FIG. 6A is a plan view for illustrating the first manufacturing method and FIG. 6B is a sectional view along VI-VI line in FIG. 6A. Next, as illustrated in FIG. 6A and FIG. 6B, the insulating layer 18 and an oxide film 20 are formed on a side wall of the dummy polysilicon layer 14. Further, after a flattening process, the surface of the insulating layer 18 is exposed, and the interlayer insulating film 22 is formed on an entire surface including the isolation region 12. As a result, the dummy polysilicon layer 14 and the polysilicon layer 14B are embedded and formed inside the interlayer insulating film 22 on the isolation region 12.

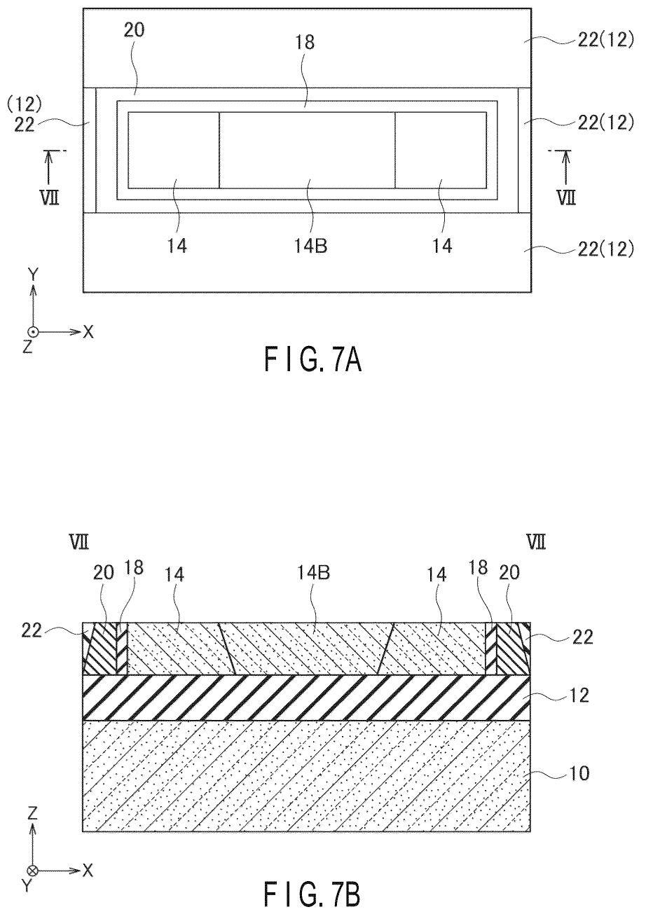

(F) FIG. 7A is a plan view for illustrating the first manufacturing method and FIG. 7B is a sectional view along VII-VII line in FIG. 7A. Next, as illustrated in FIG. 7A and FIG. 7B, by chemical mechanical polishing (CMP) technology, an entire device surface is etched back and the surfaces of the dummy polysilicon layer 14 and the polysilicon layer 14B are exposed. On a side wall surface of the dummy polysilicon layer 14, the insulating layer 18, the oxide film 20, and the interlayer insulating film 22 are successively stacked.

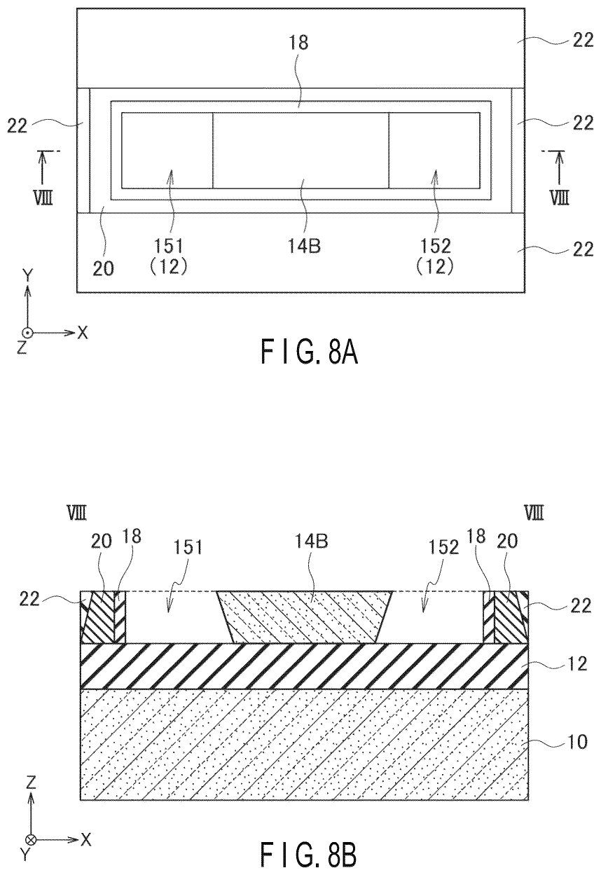

(G) FIG. 8A is a plan view for illustrating the first manufacturing method and FIG. 8B is a sectional view along VIII-VIII line in FIG. 8A. Next, as illustrated in FIG. 8A and FIG. 8B, by wet etching, the dummy polysilicon layer 14 is peeled and removed. Here, the boron-doped polysilicon layer 14B is left without being removed due to a difference in the etching rate. The surface of the isolation region 12 is exposed on bottom surfaces of recess regions 151 and 152 where the dummy polysilicon layer 14 is removed, and the insulating layer 18 is exposed on the side wall surfaces.

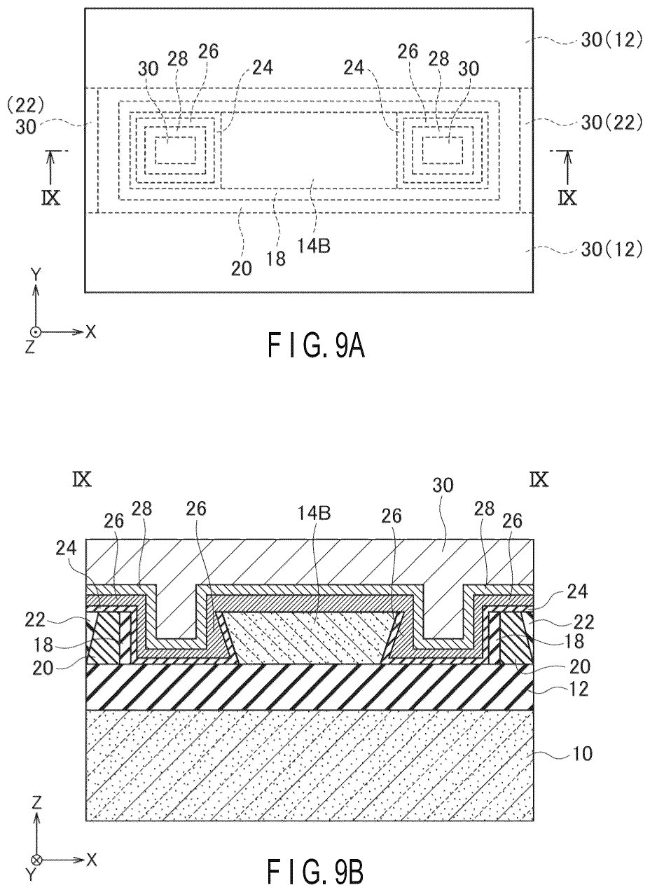

(H) FIG. 9A is a plan view for illustrating the first manufacturing method and FIG. 9B is a sectional view along IX-IX line in FIG. 9A. Next, as illustrated in FIG. 9A and FIG. 9B, in order to form electrodes in the recess regions 151 and 152 where the dummy polysilicon layer 14 is peeled, the high-k dielectric layer 24, the metal-containing layer 26, the work function metal layer 28, and the metal electrode layer 30 are successively stacked on the entire device surface. The oxide film (IL) is formed for a base of the high-k dielectric layer 24, but the illustration is omitted.

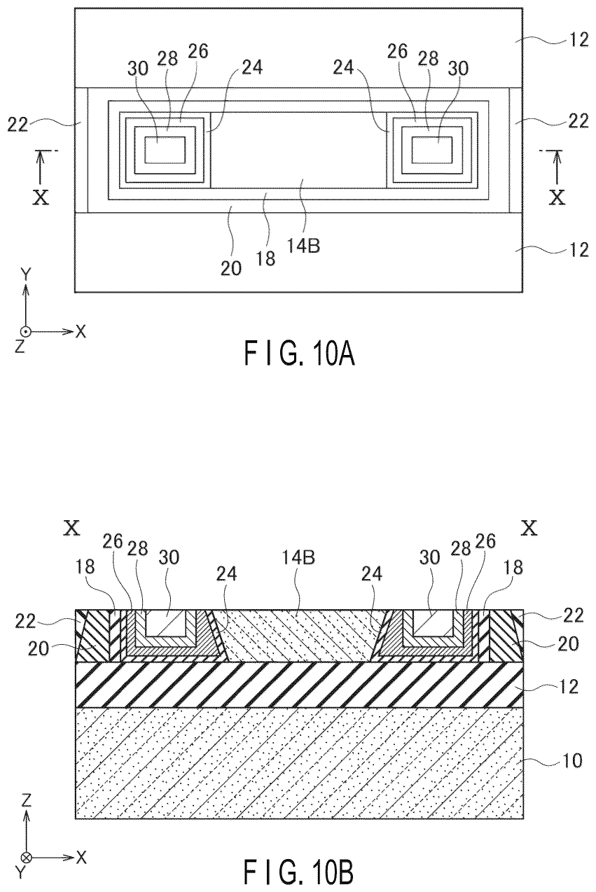

(I) FIG. 10A is a plan view for illustrating the first manufacturing method and FIG. 10B is a sectional view along X-X line in FIG. 10A. Next, as illustrated in FIG. 10A and FIG. 10B, by the CMP technology, the entire device surface is flattened, and the surface of the polysilicon layer 14B is exposed. The recess regions 151 and 152 are filled with the high-k dielectric layer 24, the metal-containing layer 26, the work function metal layer 28, and the electrode part of the metal electrode layer 30.

(J) Next, as illustrated in FIG. 1A and FIG. 1B, after forming the interlayer insulating film 34 on the entire device surface, window opening to the interlayer insulating film 34 is executed by the lithography process, and the first electrode 321 connected to the metal electrode layer 30 via the contact CS1 and the second electrode 322 connected to the metal electrode layer 30 via the contact CS2 are formed.
Second Manufacturing Method

In a second manufacturing method of the fuse 1, the isolation region 12 is formed on the semiconductor substrate 10, the non-doped dummy polysilicon layer 14 is formed on the isolation region 12, the insulating layer 18 is formed on the dummy polysilicon layer 14, the dummy polysilicon layer 14 is processed to expose the surface of the isolation region 12, the polysilicon layer 14B for which the dummy polysilicon layer 14 is doped with the impurity is formed by the lithography and the ion implantation technology, the interlayer insulating film 22 is formed on the entire surface, flattening is performed by the flattening treatment, the surface of the polysilicon layer 14B is exposed, the polysilicon layer 14B is left and the dummy polysilicon layer 14 is removed to expose the surface of the isolation region 12 by etching, the electrode layers (26, 28, and 30) are formed on the entire surface, the surfaces of the electrode layers (26, 28, and 30) and the polysilicon layer 14B are exposed flatly by the flattening treatment, the interlayer insulating film 34 is formed on the entire surface, and the first electrode 321 and the second electrode 322 are formed to the metal electrode layer 30 by patterning.

In the second manufacturing method of the fuse 1, after processing the dummy polysilicon layer 14, the ion implantation is performed and the polysilicon layer 14B is formed on a process flow. Since the ion implantation is performed on the dummy polysilicon layer 14 after processing the dummy polysilicon layer 14, high dimensional controllability is required in processes as compared with the first manufacturing method.

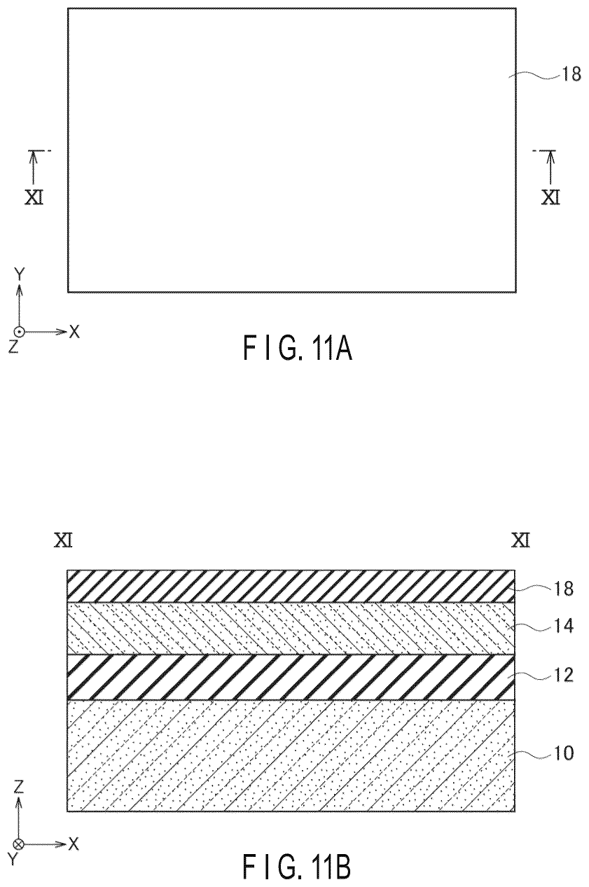

(K) FIG. 11A is a plan view for illustrating the second manufacturing method and FIG. 11B is a sectional view along XI-XI line in FIG. 11A. First, after executing the process illustrated in FIG. 1A and FIG. 1B, as illustrated in FIG. 11A and FIG. 11B, the insulating layer 18 is formed on the dummy polysilicon layer 14. Here, as the insulating layer 18, similarly to the first manufacturing method, the silicon nitride film (SiN) is used for example.

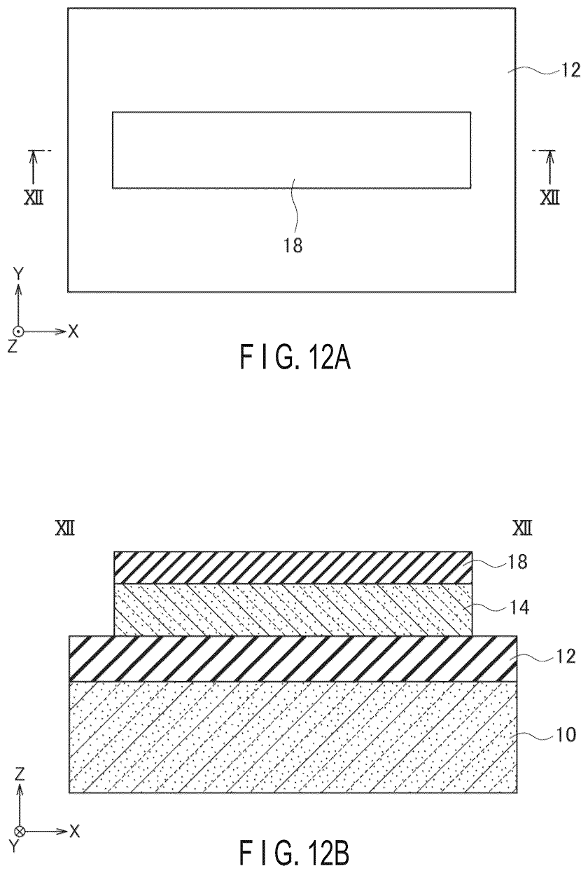

(L) FIG. 12A is a plan view for illustrating the second manufacturing method and FIG. 12B is a sectional view along XII-XII line in FIG. 12A. Next, as illustrated in FIG. 12A and FIG. 12B, with the insulating layer 18 as the hard mask, the dummy polysilicon layer 14 is removed by the etching technology such as the RIE, and the surface of the isolation region 12 is exposed. As a result, the gate-processed dummy polysilicon layer 14 is formed on the isolation region 12.

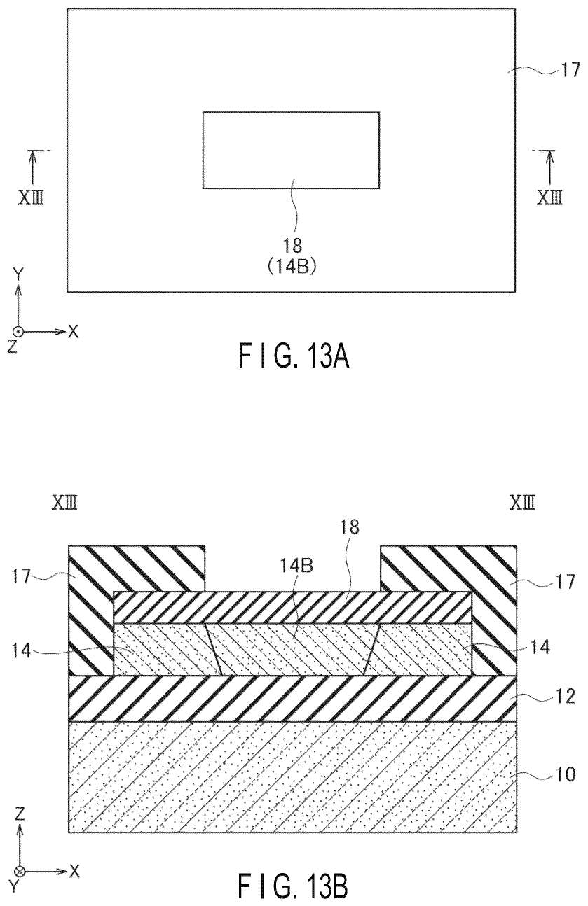

(M) FIG. 13A is a plan view for illustrating the second manufacturing method and FIG. 13B is a sectional view along XIII-XIII line in FIG. 13A. Next, as illustrated in FIG. 13A and FIG. 13B, after applying a resist layer 17 on the entire device surface, window opening to the insulating layer 18 and the dummy polysilicon layer 14 is executed by the lithography process. Further, the ion implantation of the impurity ions is performed via the insulating layer 18. Here, as the impurity, boron (B) can be used for example.

(N) Next, the resist layer 17 is peeled and the structure illustrated in FIG. 5A and FIG. 5B after the processes similar to that in the first manufacturing method is obtained.

Hereinafter, the structure illustrated in FIG. 1A and FIG. 1B is obtained through the processes (FIG. 6A and FIG. 6B to FIG. 11A and FIG. 11B) similar to that in the first manufacturing method.

### (Pattern of Contact and Polysilicon Layer)

Disposition Example 1

FIG. 14A illustrates a pattern disposition example 1 of the contact and the polysilicon layer of the fuse 1. One each of the contacts CS1 and CS2 is disposed in the metal electrode layer 30, and the polysilicon layer 14B is disposed in a straight shape in X direction. FIG. 14A is a simplest pattern disposition example. In the pattern disposition example 1, as illustrated in FIG. 14A, the polysilicon layer 14B that stretches in X direction, the metal electrode layers 30 connected to the end parts in positive and negative X directions of the polysilicon layer 14B, and the contact CS1 and the contact CS2 disposed in the metal electrode layers 30 are illustrated. The contact CS1 is connected to the first electrode 321, and the contact CS2 is connected to the second electrode 322.
Disposition Example 2

FIG. 14B illustrates a pattern disposition example 2 of the contact and the polysilicon layer of the fuse 1. In the pattern disposition example 2, as illustrated in FIG. 14B, the polysilicon layer 14B that stretches in X direction, the metal electrode layers 30 connected to the end parts in the positive and negative X directions of the polysilicon layer 14B, and contacts CS11 and CS12 and contacts CS21 and CS22 disposed in the metal electrode layers 30 are illustrated. The contacts CS11 and CS12 are connected to the first electrode 321, and the contacts CS21 and CS22 are connected to the second electrode 322. Two contacts each are disposed for the first electrode 321 and the second electrode 322 and a connection yield of the contact can be improved. By disposing the plurality of contacts for the first electrode 321 and the second electrode 322, connection resistance to the first electrode 321 and the second electrode 322 can be lowered and a fuse breaking part can be limited to the polysilicon layer 14B. Note that the number of the contacts is not limited to 2 and may be 3 or more.
Disposition Example 3

FIG. 14C illustrates a pattern disposition example 3 of the contact and the polysilicon layer of the fuse 1. In the pattern disposition example 3, as illustrated in FIG. 14C, a plurality of polysilicon layers 14B1, 14B2, and 14B3 divided in X direction, the metal electrode layer 30 connected to the polysilicon layer 14B1, the metal electrode layer 30 connected to the polysilicon layer 14B3, and the contacts CS11 and CS12 and the contacts CS21 and CS22 disposed in the metal electrode layers 30 are illustrated. The contacts CS11 and CS12 are connected to the first electrode 321, and the contacts CS21 and CS22 are connected to the second electrode 322. By providing the plurality of polysilicon layers in a fuse region, a range to be physically destroyed when breaking the fuse is prevented from being widened. In FIG. 14C, the polysilicon layer 14B2 in a range that is long in X direction at a center is a high resistance region where the fuse is to be broken. The polysilicon layers 14B1 and 14B3 that are short in X direction at both ends are regions that function as a physical barrier to limit fuse breakage. In the example in FIG. 14C, the plurality of contacts are disposed for the first electrode 321 and the second electrode 322 of the polysilicon layer, and the connection yield of the contact can be improved. Further, by disposing the plurality of contacts for the first electrode 321 and the second electrode 322, the connection resistance to the first electrode 321 and the second electrode 322 can be lowered and the fuse breaking part can be limited to the polysilicon layer 14B2. Note that metal layers 15 connecting the polysilicon layer 14B1 and the polysilicon layer 14B2 and the polysilicon layer 14B2 and the polysilicon layer 14B3 have a laminate structure similar to that of the electrode layers (26, 28, and 30).
Disposition Example 4

FIG. 14D illustrates a pattern disposition example 4 of the contact and the polysilicon layer of the fuse 1. In the pattern disposition example 4, the polysilicon layer 14B, the metal electrode layers 30 connected to the end parts in the positive and negative X directions of the polysilicon layer 14B, and the contacts CS11 and CS12 and the contacts CS21 and CS22 disposed in the metal electrode layers 30 are illustrated. The contacts CS11 and CS12 are connected to the first electrode 321, and the contacts CS21 and CS22 are connected to the second electrode 322. Two contacts each are disposed for the first electrode 321 and the second electrode 322 and the connection yield of the contact can be improved. In the example in FIG. 14D, by turning a bonding surface of the polysilicon layer 14B and the metal electrode layer 30 not into a straight shape but into a zigzag shape in a planar view, resistance of the bonding surface of the polysilicon layer 14B and the metal electrode layer 30 can be reduced by a layout pattern in addition to a sectional shape. Further, by disposing the plurality of contacts for the first electrode 321 and the second electrode 322, the connection resistance to the first electrode 321 and the second electrode 322 can be lowered and the fuse breaking part can be limited to the polysilicon layer 14B.
Disposition Example 5

FIG. 14E illustrates a pattern disposition example 5 of the contact and the polysilicon layer of the fuse 1. In the pattern disposition example 5, the fuse breaking part is formed narrow by the layout pattern to be a shape to limit the breaking part when breaking the fuse to the part of the polysilicon layer 14B. In the example in FIG. 14E, the plurality of contacts are disposed for the first electrode 321 and the second electrode 322 of the polysilicon layer, and the connection yield of the contact can be improved. Further, by disposing the plurality of contacts for the first electrode 321 and the second electrode 322, the connection resistance to the first electrode 321 and the second electrode 322 can be lowered and the fuse breaking part can be limited to the part of the polysilicon layer 14B formed narrow by the layout pattern.

### (Modification 1)

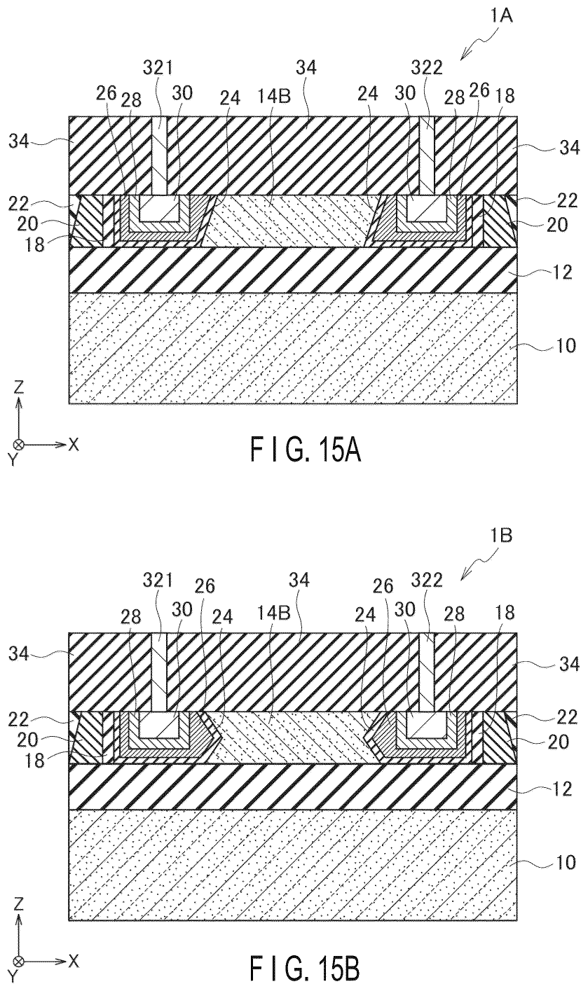

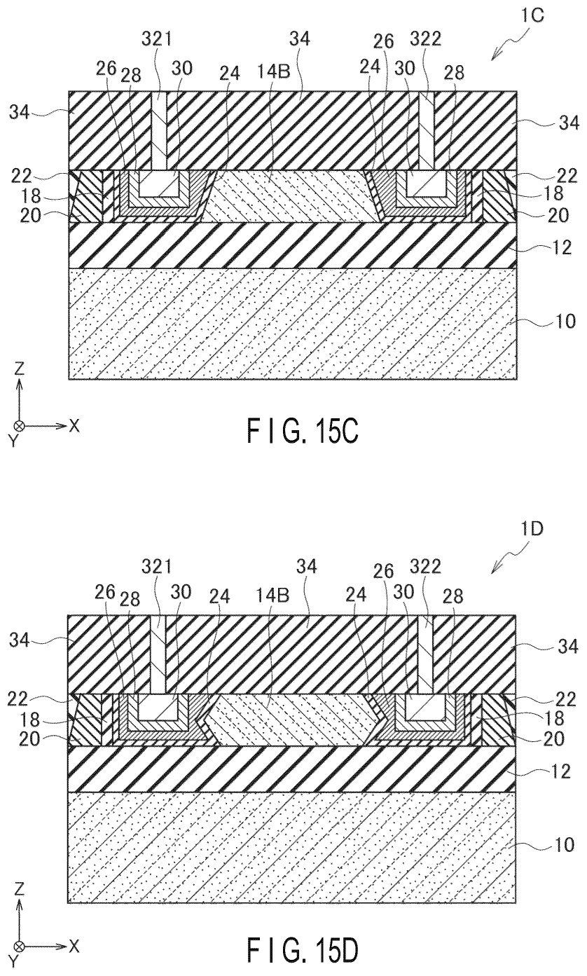

FIG. 15A is a sectional view of a fuse 1A of a semiconductor device according to a modification 1. For the fuse 1A, as illustrated in FIG. 15A, in the sectional structure along XZ plane of the polysilicon layer 14B, the first bonding surface between the polysilicon layer 14B and the electrode layers (26, 28, and 30) connected to the first electrode 321 and the second bonding surface between the polysilicon layer 14B and the electrode layers (26, 28, and 30) connected to the second electrode 322 have a bilaterally asymmetrical shape in X direction. In addition, the first bonding surface and the second bonding surface extend in Y direction and are parallel to each other. In the ion implantation process, by performing angular implantation of the impurity, both ends of the polysilicon layer 14B can be turned to an asymmetrical structure. Since this bonding part shape can widen an area as compared with the case of perpendicularly forming the bonding surface, the contact resistance of the bonding surface can be reduced.

### (Modification 2)

FIG. 15B is a sectional view of a fuse 1B of a semiconductor device according to a modification 2. For the fuse 1B, as illustrated in FIG. 15B, in the sectional structure along XZ plane of the polysilicon layer 14B, the first bonding surface and the second boning surface have a bilateral hand drum (narrow-in-the-middle) shape in X direction. Since this bonding part shape can widen the area as compared with the case of perpendicularly forming the bonding surface, the contact resistance of the bonding surface can be reduced.

### (Modification 3)

FIG. 15C is a sectional view of a fuse 1C of a semiconductor device according to a modification 3. For the fuse 1C, as illustrated in FIG. 15C, in the sectional structure along XZ plane of the polysilicon layer 14B, the first bonding surface and the second boning surface have a tapered shape in Z direction. Since this bonding part shape can widen the area as compared with the case of perpendicularly forming the bonding surface, the contact resistance of the bonding surface can be reduced.

### (Modification 4)

FIG. 15D is a sectional view of a fuse 1D of a semiconductor device according to a modification 4. For the fuse 1D, as illustrated in FIG. 15D, in the sectional structure along XZ plane of the polysilicon layer 14B, the first bonding surface and the second boning surface have a bilateral barrel (bowing/thick-in-the-middle) shape in X direction. Since this bonding part shape can widen the area as compared with the case of perpendicularly forming the bonding surface, the contact resistance of the bonding surface can be reduced.

### (Modification 5)

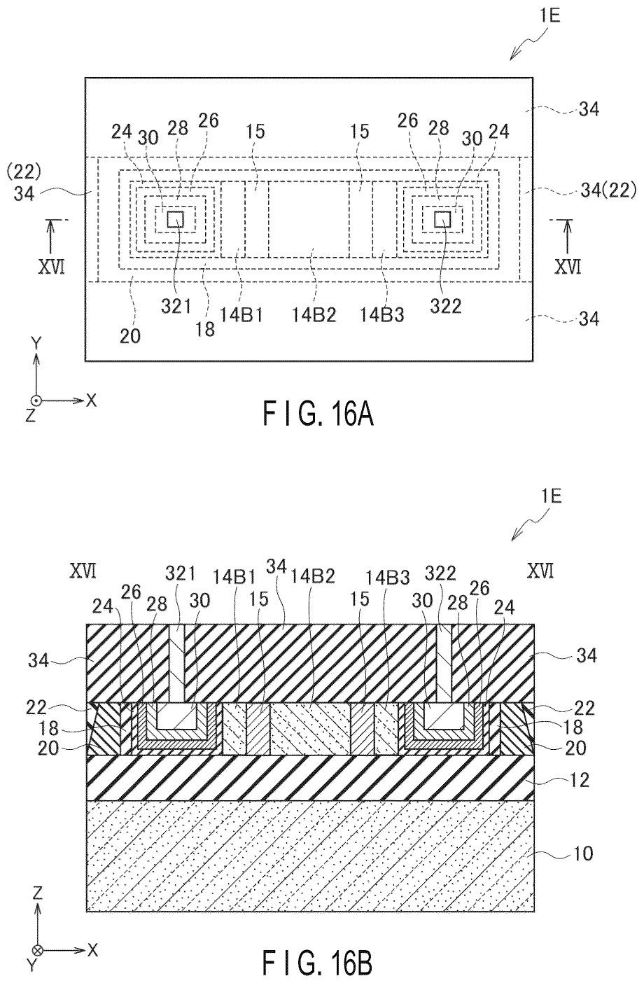

FIG. 16A is a plan view of a fuse 1E of a semiconductor device according to a modification 5. FIG. 16B is a sectional view along XVI-XVI line in FIG. 16A. The fuse 1E is provided with the plurality of divided polysilicon layers 14B1, 14B2, and 14B3. By providing the plurality of divided polysilicon layers 14B1, 14B2, and 14B3, a range to be physically destroyed when breaking the fuse is prevented from being widened. In FIG. 16A and FIG. 16B, the polysilicon layer 14B2 in the range that is long in X direction at the center is the high resistance region where the fuse is to be broken, and the polysilicon layers 14B1 and 14B3 that are short in X direction at both ends are the regions that function as the physical barrier to limit fuse breakage. Note that the metal layers 15 are formed between the polysilicon layer 14B1 and the polysilicon layer 14B2 and between the polysilicon layer 14B2 and the polysilicon layer 14B3. The metal layers 15 have the structure similar to that of the electrode layers (26, 28, and 30).

### (Transistor Structure)

FIG. 17A is a plan view of an NMOS transistor 2N configuring a CMOS in a semiconductor device according to an embodiment, and FIG. 17B is a sectional view along XVII-XVII line in FIG. 17A. FIG. 18A is a plan view of a PMOS transistor 2P configuring a CMOS in a semiconductor device according to an embodiment, and FIG. 18B is a sectional view along XVIII-XVIII line in FIG. 18A.

In such semiconductor devices, a metal gate GN of the NMOS transistor 2N and a metal gate GP of the PMOS transistor 2P configuring the CMOS can be formed by CMOS device technology for which the HKMG technology and the RMG technology are combined.

As illustrated in FIG. 17A and FIG. 17B, the NMOS transistor 2N includes the metal gate GN which is provided on an active region 10A electrically isolated by the isolation region 12 and includes the stack structure of the electrode layers (26, 28, and 30) illustrated in FIG. 1A and FIG. 1B. Here, the active region 10A can be formed by a P-type semiconductor substrate 10 or a P-well region.

As illustrated in FIG. 18A and FIG. 18B, the PMOS transistor 2P includes the metal gate GP which is provided on an active region 10B electrically isolated by the isolation region 12 and includes the stack structure of the electrode layers (26, 28, and 30) illustrated in FIG. 1A and FIG. 1B. Here, the active region 10B can be formed by an N-type semiconductor substrate 10 or an N-well region.

As illustrated in FIG. 17A and FIG. 17B, the metal gate GN includes an oxide film (IL) 23 provided on the active region 10A, the high-k dielectric layer 24 provided on the oxide film 23, a metal-containing layer 261 provided on the high-k dielectric layer 24, the work function metal layer 28 provided on the metal-containing layer 261, and the metal electrode layer 30 provided above the work function metal layer 28. In the NMOS, between the work function metal layer 28 and the metal electrode layer 30, a work function metal layer 29 and a metal-containing layer 262 are provided. The metal gate GN is embedded in an interlayer insulating film 36, as illustrated in FIG. 17A and FIG. 17B.

As illustrated in FIG. 18A and FIG. 18B, the metal gate GP includes the oxide film 23 provided on the active region 10B, the high-k dielectric layer 24 provided on the oxide film 23, the metal-containing layer 261 provided on the high-k dielectric layer 24, the work function metal layer 28 provided on the metal-containing layer 261, and the metal electrode layer 30 provided above the work function metal layer 28. In the PMOS, between the work function metal layer 28 and the metal electrode layer 30, a metal-containing layer 263, the work function metal layer 29 and the metal-containing layer 262 are provided. The metal gate GP is embedded in the interlayer insulating film 36, as illustrated in FIG. 18A and FIG. 18B.

For the metal-containing layers 261, 262, and 263, similarly to the metal-containing layer 26 used in the fuse 1, TiN, TaN, Ta or W or the like is applicable. A threshold voltage of the PMOS can be adjusted by changing a thickness of the work function metal layer 29. The work function metal layer 29 may contain a metal such as aluminum (Al) or lanthanum (La).

Thicknesses of members configuring the semiconductor devices in the present specification and a distance between the members or the like can be easily measured by physical analysis using a secondary electron microscope (SEM), for example. A position of a fuse part can be specified by planar SEM observation, and a fuse that is not broken or the like can be easily observed from sectional SEM observation.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
a semiconductor substrate including an active region and an isolation region that is electrically isolated from the active region;
a fuse disposed on the isolation region and including:
a polysilicon layer including an impurity, and
first and second electrode layers that are electrically connected to the polysilicon layer; and
a transistor disposed on the active region and including a metal gate having a stack structure of electrode layers.

2. The semiconductor device according to claim 1, wherein the fuse is electrically programmable by a voltage applied between first and second electrode layers to break the polysilicon layer.

3. The semiconductor device according to claim 1, wherein the first and second electrode layers of the fuse are provided on both ends of the polysilicon layer, and include:
a first high-k dielectric layer,
a first metal-containing layer on the first high-k dielectric layer,
a first work function metal layer on the first metal-containing layer, and
a first metal electrode layer on the first work function metal layer.

4. The semiconductor device according to claim 3, wherein the first high-k dielectric layer includes one of: hafnium oxide, hafnium silicate, tantalum oxide, strontium titanate, and zirconium oxide.

5. The semiconductor device according to claim 3, wherein the first metal-containing layer includes one of: titanium nitride, tantalum nitride, tantalum, and tungsten.

6. The semiconductor device according to claim 3, wherein the first work function metal layer includes aluminum or lanthanum.

7. The semiconductor device according to claim 3, wherein the first metal electrode layer includes tungsten (W) or aluminum (Al).

8. The semiconductor device according to claim 3, wherein the stack structure of the metal gate includes:
a second high-k dielectric layer,
a second metal-containing layer on the second high-k dielectric layer,
a second work function metal layer on the second metal-containing layer, and
a second metal electrode layer on the second work function metal layer.

9. The semiconductor device according to claim 1, wherein
the polysilicon layer extends in a first direction parallel to the semiconductor substrate, and
in a plane including the first direction and a second direction perpendicular to the semiconductor substrate, the polysilicon layer has a bilaterally symmetrical shape.

10. The semiconductor device according to claim 9, wherein the polysilicon layer has one of: a tapered shape, an inversely tapered shape, a bilateral barrel shape, and a bilateral hand drum shape.

11. The semiconductor device according to claim 1, wherein
in a plane including the first direction and a second direction perpendicular to the semiconductor substrate, the polysilicon layer has a bilaterally asymmetrical shape.

12. The semiconductor device according to claim 1, wherein the impurity of the polysilicon layer is boron, concentration of which is 1×10¹⁹ atoms/cm³ or higher.

13. A semiconductor device manufacturing method comprising:
forming an electrically programmable fuse on an isolation region of a semiconductor substrate and forming a transistor on an active region of the semiconductor substrate, the isolation region being electrically isolated from the active region, wherein
forming the fuse includes:
forming a first dummy polysilicon layer,
doping an impurity to the first dummy polysilicon layer and forming a first polysilicon layer therein,
removing the first dummy polysilicon layer by etching while leaving the first polysilicon layer, and
forming first and second electrode layers at locations from which the first dummy polysilicon layer was removed, such that the first and second electrode layers are electrically connected to the first polysilicon layer, and
forming the transistor includes:
forming a second dummy polysilicon layer,
removing the second dummy polysilicon layer by etching, and
forming a metal gate at a location from which the second dummy polysilicon layer was removed.

14. The semiconductor device manufacturing method according to claim 13, wherein the first and second electrode layers are on both ends of the first polysilicon layer on the isolation region.

15. The semiconductor device manufacturing method according to claim 13, wherein forming the first and second electrode layers includes forming:
a first high-k dielectric layer,
a first metal-containing layer on the first high-k dielectric layer,
a first work function metal layer on the first metal-containing layer, and
a first metal electrode layer on the first work function metal layer.

16. The semiconductor device manufacturing method according to claim 13, wherein
the metal gate is provided above the active region, and
forming the metal gate includes forming:
a second high-k dielectric layer,
a second metal-containing layer on the second high-k dielectric layer,
a second work function metal layer on the second metal-containing layer, and
a second metal electrode layer on the second work function metal layer.

17. The semiconductor device manufacturing method according to claim 13, further comprising:
adjusting a concentration distribution of the impurity in the first polysilicon layer to control a shape of bonding surfaces of the first polysilicon layer and the first and second electrode layers.

18. The semiconductor device manufacturing method according to claim 13, wherein
the first polysilicon layer extends in a first direction parallel to the semiconductor substrate, and
in a plane including the first direction and a second direction perpendicular to the semiconductor substrate, the first polysilicon layer has a symmetrical shape.

19. The semiconductor device manufacturing method according to claim 13, wherein the impurity is boron, concentration of which is at least 1×10¹⁹ cm⁻³ or higher.

20. A semiconductor device manufacturing method comprising:
forming an isolation region on a semiconductor substrate;
forming a dummy polysilicon layer on the isolation region;
doping an impurity to the dummy polysilicon layer and forming a first polysilicon layer therein by lithography and ion implantation technology;
applying an insulating layer from above, processing the first polysilicon layer to expose a surface of the isolation region, and applying a first interlayer insulating film from above;
performing flattening treatment and exposing a surface of the first polysilicon layer;
removing the dummy polysilicon layer to expose the surface of the isolation region by etching;
applying an electrode layer from above;
exposing surfaces of the electrode layer and the first polysilicon layer flatly by flattening treatment; and
applying a second interlayer insulating film from above, and forming first and second electrodes electrically connected to the electrode layer by patterning.
